(19) United States
(12) Patent Application Publication
(10) Pub. No.: US 2005/0224959 A1
(43) Pub. Date: Oct. 13, 2005

(54) Die with discrete spacers and die spacing method

(75) Inventors: Hyeog Chan Kwon, Seoul (KR); Geun Sik Kim, Sungnam (KR)

Correspondence Address: HAYNES BEFFEL & WOLFELD LLP, P O BOX 366, HALF MOON BAY, CA, 94019, US

(73) Assignee: ChipPAC, Inc, Fremont, CA (US)

(21) Appl. No.: 10/966,574

(22) Filed: Oct. 15, 2004

Related U.S. Application Data
(60) Provisional application No. 60/558,673, filed on Apr. 1, 2004.

(51) Int. Cl. H01L 21/44; H01L 21/48; H01L 21/50; H01L 23/34

(52) U.S. Cl. 257/723; 438/107

(57) ABSTRACT

A semiconductor die, for use in a multiple-die semiconductor chip package, has a wire bonding side and a backside. At least two discrete spacers, and preferably at least four, are secured to the die at chosen spacer positions on at least one of the wire bonding side and the backside. The spacers are configured and positioned to help maintain proper die-to-die spacing between the die and an adjacent die in a multiple-die semiconductor chip package. At least two of the discrete spacers may be secured directly to the wire bonding side. A dielectric layer may be on the backside of the die and at least two of the discrete spacers may be secured to the dielectric layer on the backside of the die.

### CROSS-REFERENCE TO RELATED APPLICATIONS

This application claims priority from U.S. Provisional Application No. 60/558,673, filed Apr. 1, 2004, titled “Die with discrete spacers and die spacing method”.

### BACKGROUND

The present invention relates to semiconductor spacer structures used in the fabrication of multi-chip modules, and to a method of maintaining proper die-to-die spacing in such packages.

To obtain the maximum function and efficiency from the minimum package, various types of increased density packages have been developed. Among these various types of packages is the multiple-die semiconductor chip package, commonly referred to as a multi-chip module, multi-chip package or stacked chip package. A multi-chip module includes one or more integrated circuit semiconductor chips, often referred to as circuit die, stacked one onto another to provide the advantages of light weight, high density, and enhanced electrical performance.

In some circumstances, such as when the upper die is smaller than the lower die, the upper die can be attached directly to the lower die without the use of spacers. However, when spacers are needed between the upper and lower die, spacer die, that is die without circuitry, or adhesives containing spacer elements, typically microspheres, are often used to properly separate the upper and lower die. See U.S. Pat. Nos. 5,323,060 and 6,472,758 and U.S. patent publication number U.S. 2003/0178710.

Wafer thinning technology is important to package development. Current wafer thinning methods include the in-line wafer B/G (BackGrinding) system and the DBG (Dicing Before Grinding) process. Wafer B/G systems have used the film adhesive process whereby the wafer is thinned by backgrinding and then is diced, that is the semiconductor wafer is separated into individual semiconductor die, typically using a laser dicing saw. Before dicing, a wafer mounting tape is typically attached to the backside of the wafer. The wafer mounting tape keeps the die together after dicing. With the DBG process, the wafer is diced before backgrinding.

The semiconductor die is typically adhered to a previously mounted die or to the substrate with a paste (typically an epoxy paste adhesive) or a film adhesive. Generally, paste adhesives have been used more often than film adhesives. However, some multi-chip modules are more successfully fabricated using film adhesives because the thickness of adhesive film is uniform so that there is minimal or no tilt of the semiconductor chips and no fillet of adhesive encircling the semiconductor chip. Moreover, no resin is bled so that it is suitable for multi chip stacking and packages with tight design tolerances or thinner chip.

In one method of fabricating a multi-chip module using film adhesive, an adhesive film is laminated directly to the backside of the semiconductor wafer and then the wafer is diced into individual semiconductor chips using conventional wafer dicing equipment. For stacking the semiconductor chips, each chip is lifted by a chip-bonding tool, which is usually mounted at the end of a pick-and-place device, and mounted onto the substrate or onto a semiconductor chip mounted previously. This method requires special film laminating equipment. However, it can shorten fabrication time and lower cost because the paste-dispensing process is not needed.

After the chip mounting process, bonding pads of the chips are connected to bonding pads of the substrate with Au or Al wires during a wire bonding process to create an array of semiconductor chip devices. Finally, the semiconductor chips and their associated wires connected to the substrate are encapsulated, typically using an epoxy-molding compound, to create an array of encapsulated semiconductor devices. The molding compound protects the semiconductor devices from the external environment, such as physical shock and humidity. After encapsulation, the encapsulated devices are separated, typically using a laser saw, into individual semiconductor chip packages.

### SUMMARY

A first aspect of the invention is directed to a semiconductor die for use in a multiple-die semiconductor chip package. The semiconductor die has a wire bonding side and a backside. At least two discrete spacers, and preferably at least four, are secured to the die at chosen spacer positions on at least one of the wire bonding side and the backside. The spacers have a chosen height. The spacers are configured and positioned to help maintain proper die-to-die spacing between the die and an adjacent die in a multiple-die semiconductor chip package. At least two of the discrete spacers may be secured directly to the wire bonding side. A dielectric layer may be on the backside of the die and at least two of the discrete spacers may be secured to the dielectric layer on the backside of the die.

A second aspect of the invention is directed to a semiconductor wafer used in producing multiple-die semiconductor chip packages. The semiconductor wafer has a wire bonding side and a backside. An array of discrete spacers is secured to the wafer at chosen spacer positions on at least one of the wire bonding side and the backside. The spacer positions are chosen so that after the wafer has been severed into a plurality of semiconductor die, each semiconductor die has at least two discrete spacers. The spacers have a chosen height. The spacers are configured and positioned to help maintain proper die-to-die spacing between one of the die and an adjacent die in a multiple-die semiconductor chip package.

A third aspect of the invention is directed to a method for maintaining proper die-to-die spacing in a multiple-die semiconductor chip package. A pattern of spacer positions for discrete spacers on a first semiconductor die is chosen. The first die has a wire bonding side and a backside. At least two, and preferably at least four, discrete spacers are secured at the spacer positions on at least one of the wire bonding side and the backside of the first die. The first die is adhered to a second die using an adhesive with the adhesive and at least two of the discrete spacers between said first and second die. The spacers are confirmed and the spacer positions are selected to help maintain proper die-to-die spacing between the first and second die in a multiple-die semiconductor chip package. The spacer pattern may be chosen to correspond to the shape of the first semiconductor die. At least two of the discrete spacers may be secured directly to the wire bonding side. The backside of the die may have a dielectric layer and at least two of the discrete spacers may be secured to the dielectric layer on the backside of the die.

A fourth aspect of the invention is directed to a method for maintaining proper die-to-die spacing in a multiple-die semiconductor chip package. A pattern of spacer positions for an array of discrete spacers on a semiconductor wafer is chosen. The semiconductor wafer has a wire bonding side and a backside. Discrete spacers are secured to the spacer positions on at least one of the wire bonding side and the backside of the wafer. The wafer is severed into a plurality of first die, each first die having at least two discrete spacers. A first die is secured to a second die using an adhesive with the adhesive and at least two of the discrete spacers between said first and second die. The discrete spacers help maintain proper die-to-die spacing between the first and second die in a multiple-die semiconductor chip package.

Various features and advantages of the invention will appear from the following description in which the preferred embodiments have been set forth in detail in conjunction with the accompanying drawings.

### BRIEF DESCRIPTION OF THE DRAWINGS

FIG. 1 shows backgrinding of the backside of a semiconductor wafer;

FIG. 2 illustrates the ground wafer of FIG. 1 secured to a dicing tape;

FIG. 3 shows the ground wafer of FIG. 2 after an array of discrete spacers has been secured to the wire bonding side of the ground wafer;

FIGS. 4, 5 and 6 illustrate three exemplary shapes for the discrete spacers of FIG. 3;

FIG. 7 is a plan view of the structure of FIG. 3 after the ground wafer has been diced to create individual semiconductor die;

FIG. 8 is an enlarged view of one of the semiconductor die of FIG. 7 showing a rectangular pattern of discrete spacers corresponding to the shape of the semiconductor die with an optional fifth spacer shown centered on the semiconductor die;

FIG. 9 shows an alternative embodiment to the pattern of FIG. 8 comprising a triangular pattern of discrete spacers;

FIG. 10 shows a further alternative embodiment to the pattern of FIG. 8 comprising a spot-type spacer, such as shown in FIGS. 4-6, and a line-type spacer;

FIG. 11 illustrates the semiconductor die of FIG. 8 mounted to a substrate with wires connecting wire bond pads on the wire bonding side of the semiconductor die to wire bond pads on the substrate;

FIG. 12 shows the structure of FIG. 11 with an adhesive applied to the wire bonding side of the semiconductor die and illustrating a second die, having a dielectric layer on one side thereof, being placed on top of the first semiconductor die;

FIG. 13 illustrates the structure of FIG. 12 after the second die has been secured to the first die with the discrete spacers and adhesive between the dielectric layer and the first die and after wires have been connected between wire bond pads on the second die and the substrate;

FIGS. 14-21 illustrate making an alternative embodiment of the invention of FIGS. 1-13;

FIG. 14 shows backgrinding of the backside of a semiconductor wafer;

FIG. 15 illustrates the ground wafer of FIG. 14 with a dielectric layer secured to the ground backside of the wafer;

FIG. 16 shows the ground wafer of FIG. 15 after an array of discrete spacers have been secured to the dielectric layer on the ground backside of the ground wafer;

FIG. 17 illustrates the structure of FIG. 16 secured to a dicing tape with the discrete spacers against the dicing tape and the wire bonding side of the ground wafer exposed;

FIG. 18 shows the structure of FIG. 17 after the ground wafer has been diced to create individual semiconductor die separated by grooves;

FIG. 19 illustrates a second die secured to a substrate with wires connecting wire bond pads on the second die and the substrate;

FIG. 20 shows the structure of FIG. 19 with an adhesive applied to the wire bonding side of the second semiconductor die and illustrating a first semiconductor die of FIG. 18, with the dielectric layer and discrete spacers adhered thereto, being placed on top of the second semiconductor die;

FIG. 21 illustrates the structure of FIG. 20 after the first semiconductor die has been secured to the second semiconductor die with the discrete spacers and adhesive between the dielectric layer and the second semiconductor die and after wires have been connected between wire bond pads on the first semiconductor die and the substrate; and

FIGS. 22, 23 and 24 illustrate the multi-die semiconductor chip packages of FIGS. 13 and 21 after mounting three different types of third semiconductor die thereon.

### DETAILED DESCRIPTION

The invention will now be described in further detail by reference to the drawings, which illustrate alternative embodiments of the invention. The drawings are diagrammatic, showing features of the invention and their relation to other features and structures, and are not made to scale. For improved clarity of presentation, in the FIGs. illustrating embodiments of the invention, elements corresponding to elements shown in other drawings are not all particularly renumbered, although they are all readily identifiable in all the FIGs.

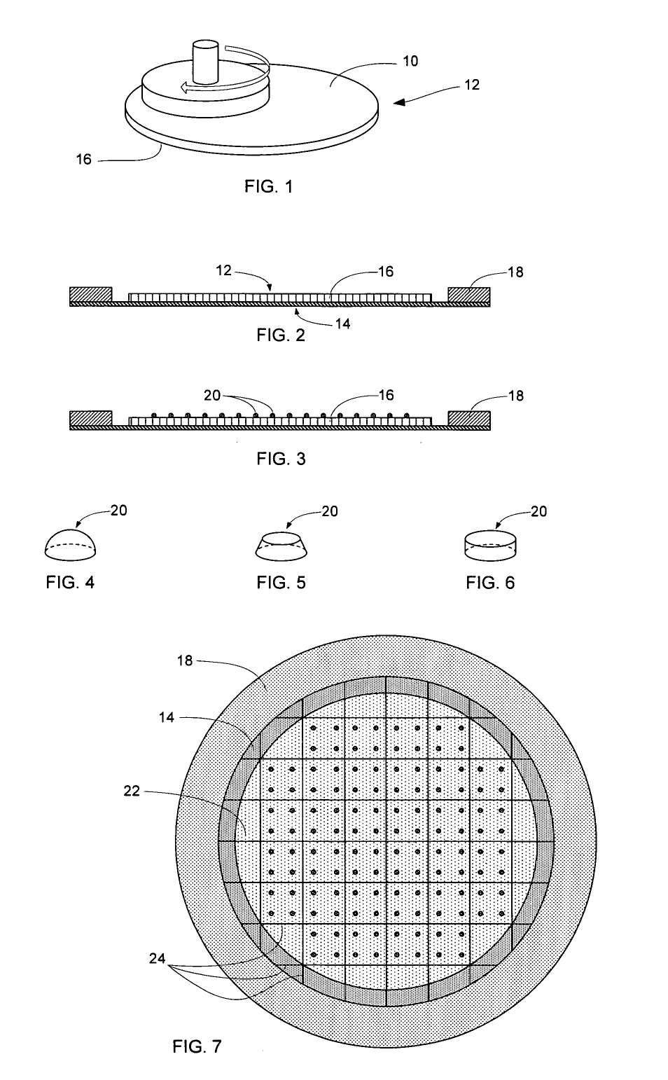

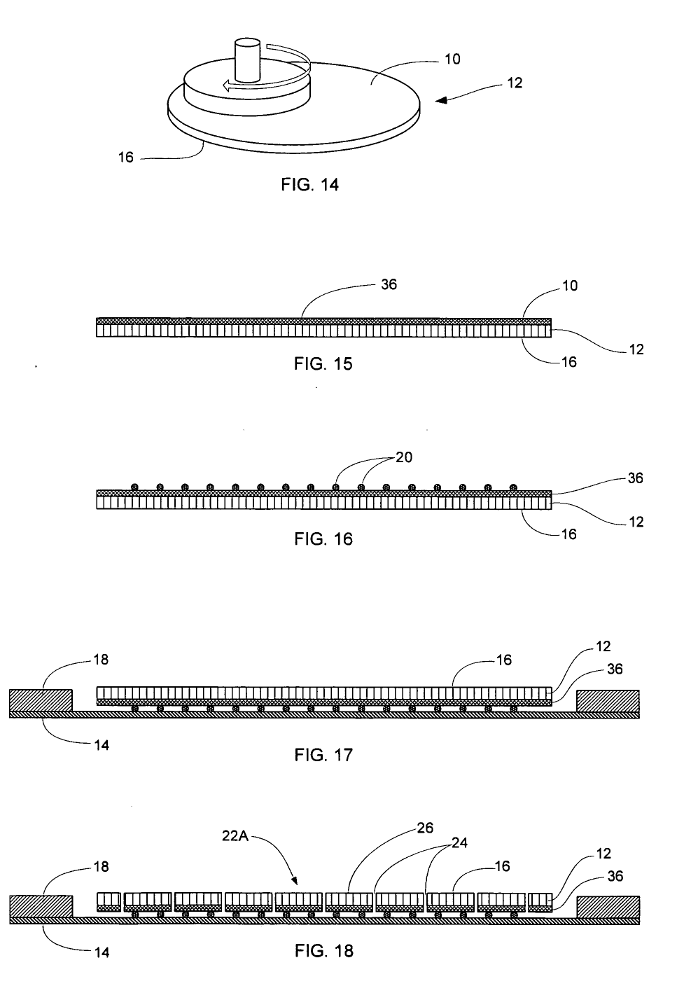

FIGS. 1-11 illustrate a first aspect of the invention in which discrete spacers are secured to the wire bonding side of the ground wafer. FIGS. 14-21 illustrate a second aspect of the invention in which discrete spacers are secured to a dielectric layer covering the backside of the ground wafer.

FIG. 1 shows backgrinding of the backside 10 of a semiconductor wafer 12. Backside 10 may be polished if needed. Ground wafer 12 is shown in FIG. 2 secured to a dicing tape 14 with the wire bonding side 16 exposed. A ring frame 18 stabilizes the periphery of dicing tape 14.

FIG. 3 shows ground wafer 12 of FIG. 2 after an array of discrete spacers 20 have been secured to wire bonding side 16 of the ground wafer. A preferred method for securing discrete spacers 20 to ground wafer 12 is through wafer scale stencil printing techniques. Stencil printing techniques can be used to print equal size discrete spacers 20, sometimes referred to as nubbins, to provide the necessary height control to maintain an even bond line thickness for stack chip applications and semiconductor packaging. Because of its wafer scale nature, an economy of scale can be realized to reduce total manufacturing costs. In most of the figures discrete spacers 20 are shown as spheres for purposes of illustration. However, in practice they would typically be generally hemispherical, as shown in FIG. 4, or other appropriate shapes, such as a truncated conical shape shown in FIG. 5 or a cylindrical shape shown in FIG. 6.

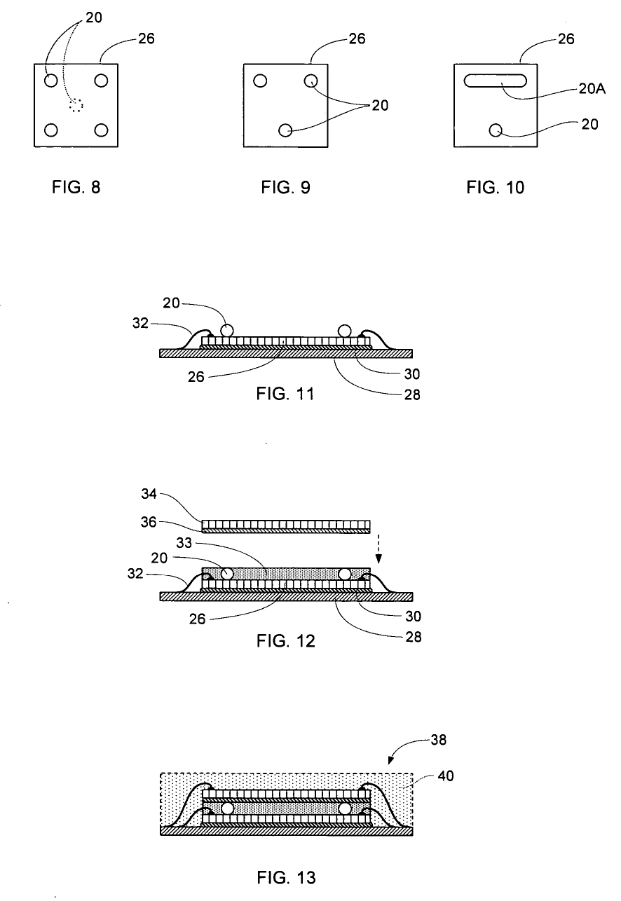

FIG. 7 is a plan view of the structure of FIG. 3 after ground wafer 12 has been diced form a diced wafer 22 with grooves 24 separating individual semiconductor die 26 created by the dicing process. FIG. 8 is an enlarged view of one of the semiconductor die 26 of FIG. 7 showing a rectangular pattern of discrete spacers 20 corresponding to the shape of the semiconductor die. Discrete spacers 20 are preferably made of a dielectric material, such as a compliant polymer material, for example a silicone-based polymer, having appropriate mechanical properties to separate upper and lower die without physically damaging either and without creating electrical pathways between the die. The number, height, separation and positioning of discrete spacers 20 depends upon factors such as the location of the wire bond pads on semiconductor die 26 the size of semiconductor die 26, the number of die to be stacked, and similar considerations. An optional fifth discrete spacer 20 is shown in dashed lines centered on semiconductor die 26. FIG. 9 shows an alternative embodiment to the pattern of FIG. 8 comprising a triangular pattern of discrete spacers 20. FIG. 10 shows a further alternative embodiment to the pattern of FIG. 8 comprising a spot-type discrete spacer 20, such as shown in FIGS. 4-6, and a line-type discrete spacer 20A.

FIG. 11 illustrates the semiconductor die 26 of FIG. 8 mounted to a substrate 28 using a suitable adhesive 30, typically an epoxy or film type adhesive. Wire bond techniques are used to connect wires 32 to wire bond pads on wire bonding side 16 of semiconductor die 26 to wire bond pads on substrate 28. FIG. 12 shows the structure of FIG. 11 with an adhesive 33, such as Loctite QMI536, applied to wire bonding side 16 of semiconductor die 26. A second, upper semiconductor die 34, having a dielectric layer 36 on the backside 10 thereof, is shown being placed on top of the first, lower semiconductor die 26. Dielectric layer 36 may not always be necessary. Dielectric layer 36 may be formed by securing a dielectric film adhesive, such as Hitachi DF series, to backside 10. FIG. 13 illustrates the structure of FIG. 12 after second, upper die 34 has been secured to first, lower die 26 with discrete spacers 20 and adhesive 33 between dielectric layer 36 and first, lower die 26 and after wires 32 have been connected between wire bond pads on second, upper die 34 and substrate 28 to create a multi-die semiconductor chip package 38. Package 38 is typically encapsulated within an epoxy molding compound 40, shown in FIG. 13 in dashed lines.

FIGS. 14-21 illustrate making an alternative embodiment of the invention of FIGS. 1-13 with like elements referred to with like reference numerals. FIG. 14 shows backgrinding of backside 10 of semiconductor wafer 12. FIG. 15 illustrates ground wafer 12 of FIG. 14 with a dielectric layer 36 secured to ground backside 10 of the wafer.

FIG. 16 shows wafer 12 of FIG. 15 after an array of discrete spacers 20 has been secured to dielectric layer 36 on ground backside 10 of the wafer. This differs from the embodiment shown in FIG. 3 in that discrete spacers 20 are secured to wire bonding side 16 in FIG. 3 while discrete spacers 20 are secured opposite backside 10 in FIG. 16. FIG. 17 illustrates the structure of FIG. 16 secured to dicing tape 14 with discrete spacers 20 against the dicing tape and wire bonding side 16 of ground wafer 12 exposed; this is essentially the opposite of the situation shown in FIG. 3.

FIG. 18 shows the structure of FIG. 17 after ground wafer 12 has been diced to create individual semiconductor die 26 separated by grooves 24.

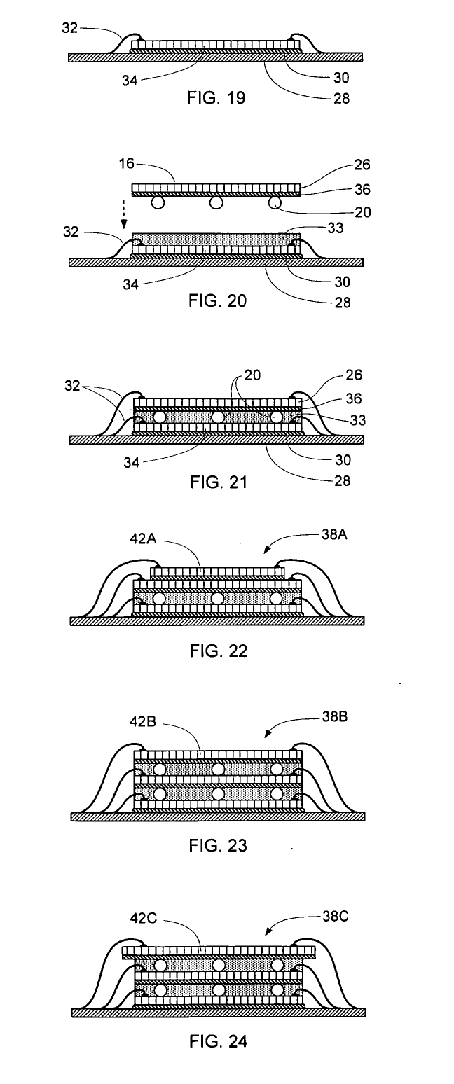

A second, lower die 34 is shown in FIG. 19 secured to substrate 28 with wires 32 connecting wire bond pads on the second die and the substrate. FIG. 20 shows the structure of FIG. 19 with adhesive 33 applied to wire bonding side 16 of second, lower die 34 and illustrating a first, upper die 26, with dielectric layer 36 and discrete spacers 20 attached thereto, being placed on top of lower die 34. FIG. 21 illustrates the structure of FIG. 20 after upper die 26 has been secured to lower die 34 with discrete spacers 20 and adhesive 33 between dielectric layer 36 and lower die 34 and after wires 32 have been connected between wire bond pads on upper die 26 and substrate 28.

FIGS. 22, 23 and 24 illustrate the multi-die semiconductor chip packages of FIGS. 13 and/or 21 after mounting three different types of third semiconductor die thereon. In FIG. 22 upper die 42A is sufficiently smaller than the middle die directly below so that spacers are not needed. In FIGS. 23 and 24 upper die 42B and 42C are the same size or larger than the middle die directly below. Upper die 42B and upper die 42C of semiconductor chip packages 38B and 38C can be secured to the middle die using discrete spacers 20 secured to (1) backside 10 of the upper die 42B and/or die 42C through dielectric film 36, as taught in FIGS. 14-21, or (2) wire bonding side 16 of either or both of the middle die of FIGS. 23 and 24 as taught in FIGS. 2-13. Option (2) is available if the lower and middle die were secured to one another using the method taught in FIGS. 1-13 or if the middle die were processed according to FIGS. 2-13 and FIGS. 15-21 with discrete spacers 20 on both sides of the middle die, typically on the dielectric layer 36 opposite backside 10 and on wire bonding side 16.

Other modification and variation can be made to the disclosed embodiments without departing from the subject of the invention as defined in following claims. For example, while the die to which spacer elements 20 are secured are typically circuit die, in appropriate cases spacer elements 20 may be secured to spacer die, that is die without circuitry or bonding pads. Therefore, in such cases what is called the wire bonding side will be the side opposite the ground backside.

Any and all patents, patent applications and printed publications referred to above are incorporated by reference.

Other embodiments are within the scope of the invention.

1. A semiconductor die, used in a multiple-die semiconductor chip package, comprising:
a semiconductor die having a wire bonding side and a backside;
at least two discrete spacers secured to the die at chosen spacer positions on at least one of the wire bonding side and the backside;
the spacers having a chosen height; and
the spacers being configured and positioned to help maintain proper die-to-die spacing between said die and an adjacent die in a multiple-die semiconductor chip package.

2. The semiconductor die according to claim 1 comprising at least four of said discrete spacers.

3. The semiconductor die according to claim 1 comprising at least four of said discrete spacers.

4. The semiconductor die according to claim 1 wherein the discrete spacers have one chosen height.

5. The semiconductor die according to claim 1 wherein at least two of the discrete spacers are secured to the wire bonding side.

6. The semiconductor die according to claim 1 wherein at least two of the discrete spacers are secured directly to the wire bonding side.

7. The semiconductor die according to claim 1 wherein at least two of the discrete spacers are secured to the backside.

8. The semiconductor die according to claim 1 further comprising a dielectric layer on the backside of the die and wherein at least two of the discrete spacers are secured to the dielectric layer on the backside of the die.

9. The semiconductor die according to claim 1 wherein the discrete spacers have at least one of the following shapes: a generally hemispherical shape, a generally cylindrical shape and a generally truncated conical shape.

10. A semiconductor die, used in a multiple-die semiconductor chip package, comprising:
a semiconductor die having a wire bonding side and a backside;
at least four discrete spacers secured to the die at chosen spacer positions on at least one of the wire bonding side and the backside;
the spacers having one chosen height;
wherein when the discrete spacers are on the wire bonding side, the discrete spacers are secured directly to the wire bonding side;
wherein when the discrete spacers are on the backside;
further comprising a dielectric layer on the backside of the die; and
the discrete spacers are secured to the dielectric layer on the backside of the die; and
the spacers being configured and positioned to help maintain proper die-to-die spacing between said die and an adjacent die in a multiple-die semiconductor chip package.

11. A semiconductor wafer, used in producing multiple-die semiconductor chip packages, comprising:
a semiconductor wafer having a wire bonding side and a backside;
an array of discrete spacers secured to the wafer at chosen spacer positions on at least one of the wire bonding side and the backside;
the spacer positions chosen so that after the wafer has been severed into a plurality of semiconductor die, each semiconductor die has at least two discrete spacers;
the spacers having a chosen height; and
the spacers being configured and positioned to help maintain proper die-to-die spacing between one of said die and an adjacent die in a multiple-die semiconductor chip package.

12. A method for maintaining proper die-to-die spacing in a multiple-die semiconductor chip package comprising:
choosing a pattern of spacer positions for discrete spacers on a first semiconductor die, the first die having a wire bonding side and a backside;
securing at least two discrete spacers at the spacer positions on at least one of the wire bonding side and the backside of the first die;
adhering the first die to a second die using an adhesive with the adhesive and at least two of the discrete spacers between said first and second die; and
configuring the spacers and selecting the spacer positions to help maintain proper die-to-die spacing between the first and second die in a multiple-die semiconductor chip package.

13. The method according to claim 12 wherein the pattern choosing step chooses a pattern corresponding to the shape of the first semiconductor die.

14. The method according to claim 12 wherein the securing step comprises securing at least four discrete spacers to the spacer positions.

15. The method according to claim 12 wherein the securing step comprises securing at least two of the discrete spacers to the wire bonding side.

16. The method according to claim 12 wherein the securing step comprises securing at least two of the discrete spacers directly to the wire bonding side.

17. The method according to claim 12 wherein the securing step comprises securing at least two of the discrete spacers to the backside.

18. The method according to claim 12 further comprising securing a dielectric layer on the backside of the die, and wherein the securing step comprises securing at least two of the discrete spacers to the dielectric layer on the backside of the die.

19. A method for maintaining proper die-to-die spacing in a multiple-die semiconductor chip package comprising:
choosing a pattern of spacer positions for discrete spacers on a first semiconductor die, the pattern corresponding to the shape of the first semiconductor die, the first die having a wire bonding side and a backside;
securing at least four discrete spacers to the spacer positions on at least one of the wire bonding side and the backside of the first die;
adhering the first die to a second die using an adhesive with the adhesive and at least four of the spacers between said first and second die;
the securing step comprising securing at least four of the discrete spacers directly to the wire bonding side when the discrete spacers are on the wire bonding side;
when the discrete spacers are on the backside:
further comprising securing a dielectric layer on the backside of the die; and
the securing step comprising securing at least four of the discrete spacers to the dielectric layer on the backside of the die the semiconductor die; and
configuring the spacers and selecting the spacer positions to help maintain proper die-to-die spacing between the first and second die in a multiple-die semiconductor chip package.

20. A method for maintaining proper die-to-die spacing in a multiple-die semiconductor chip package comprising:
choosing a pattern of spacer positions for an array of discrete spacers on a semiconductor wafer, the semiconductor wafer having a wire bonding side and a backside;
securing discrete spacers to the spacer positions on at least one of the wire bonding side and the backside of the wafer;
severing the wafer into a plurality of first die, each said first die having at least two discrete spacers; and
adhering a first said die to a second die using an adhesive with the adhesive and at least two of the discrete spacers between said first and second die;
whereby the discrete spacers help maintain proper die-to-die spacing between the first and second die in a multiple-die semiconductor chip package.
